(19) United States
(12) Patent Application Publication
(10) Pub. No.: US 2026/0322362 A1
(43) Pub. Date: Oct. 15, 2026

(54) APPARATUS HAVING A CIRCUITRY FOR TRANSFERRING ELECTRICAL CURRENT

(71) Applicant: KING FAHD UNIVERSITY OF PETROLEUM AND MINERALS, Dhahran (SA)

(72) Inventors: Ahmed Reda MOHAMED, Dhahran (SA); Muneer Ahmed AL ABSI, Dhahran (SA)

(73) Assignee: KING FAHD UNIVERSITY OF PETROLEUM AND MINERALS, Dhahran (SA)

(21) Appl. No.: 19/180,036

(22) Filed: Apr. 15, 2025

(51) Int. Cl. H03K 5/02; H03K 5/00

(52) U.S. Cl. CPC H03K 5/02; H03K 2005/00286

(57) ABSTRACT

An apparatus having a circuitry for transferring electrical current includes a voltage-controlled current source (VCCS) component with a pair of input terminals, where an input voltage signal is applied at a first input terminal. A feedback network is connected to the VCCS output and the first input terminal, performing a phase-shifting operation on the output voltage signal and feeding back a first phase-shifted voltage signal. A feedforward network is connected to the VCCS output and generates an output current signal at an output terminal. The feedforward network applies a second phase-shifting operation to the voltage signal, influencing the output current signal. The impedance of the feedforward network determines a specified gain of the output current signal over an input current signal at the first input terminal.

### BACKGROUND

### Technical Field

The present disclosure is directed to electronic circuits, specifically current conveyor circuits, designed for signal processing, particularly in biomedical applications. More specifically, the present disclosure relates to modified second-generation current conveyor (CCII) circuits utilizing CMOS technology for low-power, high-precision signal processing of weak, low-frequency signals.

### Description of Related Art

The background description provided herein is for the purpose of generally presenting the context of the disclosure. Work of the presently named inventors, to the extent it is described in this background section, as well as aspects of the description which may not otherwise qualify as prior art at the time of filing, are neither expressly nor impliedly admitted as prior art against the present invention.

Current conveyor circuits have been extensively used in analog signal processing due to their ability to efficiently transfer current while maintaining voltage stability. One of the most widely implemented architectures is the Second-Generation Current Conveyor (CCII), which has found applications in impedance converters, analog filters, oscillators, and various other signal-processing circuits. The fundamental operation of a CCII circuit involves transferring current from an input terminal to an output terminal while ensuring that the voltage at a designated node remains unaffected by the current transfer process. This characteristic makes current conveyors an attractive choice for analog signal-processing tasks that require precise current manipulation.

As analog circuit design continues to advance, there is an increasing demand for configurable and scalable current processing elements, particularly in fields such as biomedical electronics, impedance scaling, and high-frequency signal processing. Various modifications and enhancements have been introduced in current conveyor architectures to improve performance metrics such as gain, bandwidth, power consumption, and circuit stability. Some approaches have incorporated additional gain stages and feedback networks to achieve better performance in specific applications. Despite these improvements, conventional current conveyors still suffer from several fundamental limitations that restrict their effectiveness in modern circuit design.

The development of high-performance electronic circuits for biomedical applications requires efficient methods for transferring electrical signals with minimal distortion and noise. Most biosignals span frequencies from sub-hertz to a few hertz, with amplitudes ranging from a few microvolts to tens of millivolts. Due to their low amplitude and frequency range, biosignals are highly susceptible to various disturbances, including power line interference at 50-60 Hz and internal circuit noise. These interferences can significantly degrade signal quality, making it essential to use signal conditioning circuits that can filter out unwanted noise while preserving the integrity of the desired signals.

One of the primary challenges in biosignal processing is the implementation of ultra-low pass filters (LPFs) with extremely low cut-off frequencies in the sub-hertz region. Achieving such low cut-off frequencies requires either a high resistance or a large capacitance. However, an integrated capacitor of 100 pF may occupy around 0.1 mm² of silicon area, making the implementation impractical for compact designs. To overcome this limitation, capacitance multipliers (CMs) have been proposed as a viable solution for generating large effective capacitances using smaller physical capacitors. Various techniques utilizing voltage-mode and current-mode approaches have been explored for implementing capacitance multipliers. Among these, current-mode circuits offer significant advantages, including better performance at low supply voltages and enhanced robustness to process, voltage, and temperature (PVT) variations compared to voltage-mode circuits.

Current-mode circuits can be realized using different architectures, including current conveyor circuits such as first-generation current conveyors (CCI) and second-generation current conveyors (CCII). Over the past few years, several research initiatives have demonstrated the capabilities of CCII-based architectures, leading to the development of various current conveyor circuit designs. These circuits play a crucial role in signal processing applications, particularly in biomedical devices where precise current control and noise filtering are critical.

Given the growing demand for efficient current-mode circuits with high stability, low power consumption, and compact design, there is a need for innovative circuit architectures that can optimize current transfer while minimizing noise and interference.

Therefore, there is a need for efficient circuit architectures that address the challenges associated with current-mode signal processing, enabling optimal performance with minimal interference and silicon area consumption.

### SUMMARY

In an exemplary embodiment, an apparatus is provided for transferring electrical current. The apparatus includes a voltage-controlled current source (VCCS) component having a pair of input terminals, where an input voltage signal is applied at a first input terminal of the pair of input terminals. The apparatus further includes a feedback network connected to an output of the VCCS component and the first input terminal. Additionally, the apparatus includes a feedforward network connected to the output of the VCCS component and configured to produce an output current signal at an output terminal of the apparatus. The feedback network performs a phase-shifting operation on a voltage signal at an output of the VCCS component and feeds back a first phase-shifted voltage signal to the first input terminal. The feedforward network performs a phase-shifting operation on the voltage signal to generate a second phase-shifted voltage signal at the output terminal. The second phase-shifted voltage signal causes the output current signal to flow through the feedforward network, where the feedforward network controls a specified gain of the output current signal over an input current signal at the first input terminal based on an impedance of the feedforward network.

In some embodiments, the feedback network includes “N” number of inverter components connected in parallel, and the feedforward network includes “M” number of inverter components connected in parallel.

In some embodiments, the specified gain of the output current signal is determined based on a ratio of M:N.

In some embodiments, the specified gain of the output current signal is dependent on the ratio of M:N when electrical characteristics of inverters in the feedback network and the feedforward network match.

In some embodiments, the first input terminal has a lower impedance compared to the impedance at the output terminal.

In some embodiments, the specified gain is configured to be unity by adjusting impedances of the feedback network and the feedforward network.

In some embodiments, the specified gain is configured to be unity based on a first resistance value of the feedback network and an open loop gain of the VCCS component being increased to cause an impedance of the first terminal to be lesser than a first specified threshold, where the open loop gain of the VCCS component is determined based on an output resistance value of the VCCS component and a total output impedance of the VCCS component. Additionally, a second resistance value of the feedforward network is increased to cause an impedance of the output terminal to be greater than a second specified threshold.

In some embodiments, the total output impedance of the VCCS component is determined based on input impedances of the feedback network and the feedforward network.

In some embodiments, the first resistance value of the feedback network is configured to be greater than a specified threshold resistance for a voltage gain of the apparatus to be unity or less than a third specified threshold, where the voltage gain is determined based on an output voltage signal at the output terminal and the input voltage signal at the first input terminal.

In some embodiments, the output current signal is determined based on the voltage signal at the output of the VCCS component and a combined impedance of the feedback network and the feedforward network.

In some embodiments, the feedback network is configured to restrict a specified voltage gain of an output voltage signal over the input voltage signal to be unity by providing a negative feedback to the first input terminal.

In some embodiments, the circuitry is integrated into a biomedical device.

In an exemplary embodiment, a current conveyor apparatus is provided for transferring electrical current. The apparatus includes a voltage-controlled current source (VCCS) component having a pair of input terminals, where an input voltage signal is applied at a first input terminal of the pair of input terminals. The apparatus further includes a feedback network including “N” number of inverter components connected in parallel, where the feedback network is connected to an output of the VCCS component and the first input terminal. Additionally, the apparatus includes a feedforward network including “M” number of inverter components connected in parallel, where the feedforward network is connected to the output of the VCCS component and configured to produce an output current signal at an output terminal of the apparatus. The output current signal has a specified gain that is determined based on a ratio of M:N.

In some embodiments, the feedback network performs a phase-shifting operation on a voltage signal at an output of the VCCS component and feeds back a first phase-shifted voltage signal to the first input terminal.

In some embodiments, the feedforward network performs a phase-shifting operation on the voltage signal to generate a second phase-shifted voltage signal at the output terminal. The second phase-shifted voltage signal causes the output current signal to flow through the feedforward network.

In some embodiments, the feedforward network controls the specified gain of the output current signal based on an impedance of the feedforward network.

In some embodiments, the specified gain of the output current signal is dependent on the ratio of M:N when electrical characteristics of the inverters in the feedback network and the feedforward network match.

In some embodiments, the specified gain is configured to be unity by adjusting impedances of the feedback network and the feedforward network, where the adjusting includes increasing a first resistance value of the feedback network and an open loop gain of the VCCS component to cause an impedance of the first terminal to be lesser than a first specified threshold. The open loop gain of the VCCS component is determined based on an output resistance value of the VCCS component and a total output impedance of the VCCS component. Additionally, increasing a second resistance value of the feedforward network causes an impedance of the output terminal to be greater than a second specified threshold.

In some embodiments, the first resistance value of the feedback network is configured to be greater than a specified threshold resistance for a voltage gain of the apparatus to be unity or less than a third specified threshold, where the voltage gain is determined based on an output voltage signal at the output terminal and the input voltage signal at the first input terminal.

In some embodiments, the feedback network is configured to restrict a specified voltage gain of an output voltage signal over the input voltage signal to be unity by providing a negative feedback to the first input terminal.

In another exemplary embodiment, the foregoing general description of the illustrative embodiments and the following detailed description thereof are merely exemplary aspects of the teachings of this disclosure and are not restrictive.

### BRIEF DESCRIPTION OF THE DRAWINGS

A more complete appreciation of this disclosure and many of the attendant advantages thereof will be readily obtained as the same becomes better understood by reference to the following detailed description when considered in connection with the accompanying drawings, wherein:

FIG. 1A illustrates an exemplary representation of a symbol of an apparatus having circuitry for transferring electrical current, according to an embodiment.

FIG. 1B illustrates an exemplary representation of a conceptual building block of the apparatus having circuitry for transferring electrical current, according to an embodiment.

FIG. 1C illustrates an exemplary representation of a circuit architecture of the apparatus having circuitry for transferring electrical current, according to an embodiment.

FIG. 1D illustrates another exemplary representation of a circuit architecture of the apparatus having circuitry for transferring electrical current, according to an embodiment.

FIG. 2 illustrates an exemplary representation of a small signal equivalent circuit, according to an embodiment.

FIG. 3 illustrates another exemplary representation of a circuit architecture of the apparatus with β=(15/1) having the circuitry for transferring electrical current, according to an embodiment.

FIG. 4 illustrates another exemplary representation of a layout of the apparatus with β=(15/1) having circuitry for transferring electrical current, according to an embodiment.

FIG. 5A illustrates a graphical representation of a pre- and post-layout simulation results of a voltage gain (a), according to an embodiment.

FIG. 5B illustrates a graphical representation of a pre- and post-layout simulation results of the voltage gain (a), according to an embodiment.

FIG. 6A illustrates a graphical representation of a pre- and post-layout simulation results of a current gain, according to an embodiment.

FIG. 6B illustrates a graphical representation of a pre- and post-layout simulation results of a current gain, according to an embodiment.

FIG. 7 illustrates a graphical representation of impedances at X, Y, and Z terminals of the apparatus with β=(15/1) having circuitry for transferring electrical current, according to an embodiment.

FIG. 8 illustrates a graphical representation of Loop gain and phase at C_{L} of 0.5 Pf of the apparatus having circuitry for transferring electrical current, according to an embodiment.

FIG. 9A illustrates a Conceptual block diagram of a Photo Plethysmo Graphy (PPG) sensor front-end, according to an embodiment.

FIG. 9B illustrates a Low Pass Filter (LPF) based on the march, according to an embodiment.

FIG. 10 illustrates a graphical representation of the effectiveness of LPF based on the apparatus having circuitry for transferring electrical current, according to an embodiment.

FIG. 11 is an illustration of a non-limiting example of details of computing hardware used in a computing system, according to certain embodiments.

FIG. 12 is an exemplary schematic diagram of a data processing system used within the computing system, according to certain embodiments.

FIG. 13 is an exemplary schematic diagram of a processor used with the computing system, according to certain embodiments.

FIG. 14 is an illustration of a non-limiting example of distributed components which may share processing with a controller, according to certain embodiments.

### DETAILED DESCRIPTION

In the drawings, like reference numerals designate identical or corresponding parts throughout the several views. Further, as used herein, the words “a”, “an” and the like generally carry a meaning of “one or more”, unless stated otherwise.

Furthermore, the terms “approximately,” “approximate”, “about” and similar terms generally refer to ranges that include the identified value within a margin of 20%, 10%, or preferably 5%, and any values therebetween.

In various aspects of the disclosure, non-limiting definitions of one or more terms that will be used in the document are provided below.

The term “Voltage-Controlled Current Source (VCCS)” refers to an electronic circuit that generates an output current proportional to an applied input voltage. The VCCS serves as a fundamental building block in current-mode signal processing applications and is widely used in applications such as analog computing and active filters.

The term “Feedback Network” refers to a circuit configuration that takes a portion of the output signal and feeds it back to the input terminal, typically to control gain, enhance stability, or modify signal characteristics.

The term “Feedforward Network” refers to a circuit configuration that processes an input signal in a forward direction to influence the final output, often used for gain control, signal shaping, or phase correction.

The term “Phase-Shifting Operation” refers to a process in which the phase of a signal is altered by a specific angle, commonly achieved using reactive components such as capacitors and inductors to control signal timing and alignment.

The term “Impedance” refers to the opposition to the flow of alternating current in a circuit, measured in ohms (Ω), and determined by resistance, capacitance, and inductance characteristics.

The term “Output Current Signal” refers to the electrical current produced at the output terminal of a circuit, influenced by the applied input voltage, circuit topology, and gain characteristics.

The term “Input Voltage Signal” refers to the electrical potential difference applied at the input terminal of a circuit, serving as the driving force for generating an output response.

The term “Gain” refers to the ratio of output signal magnitude to input signal magnitude, often expressed in decibels (dB), indicating the amplification or attenuation applied by a circuit.

The term “Modified Second-Generation Current Conveyor circuit (M-CCII)” refers to a current-mode circuit designed to enhance signal processing capabilities. The M-CCII provides improved linearity, gain control, and stability, making it suitable for applications such as current-mode filtering and amplification.

The term “Operational Transconductance Amplifier (OTA)” refers to an amplifier that converts an input voltage into an output current. The OTA is commonly used in analog signal processing applications, including filters, oscillators, and modulators, due to its voltage-controlled current-driving capability. In some embodiments, the terms VCCS and OTA may be used interchangeably.

The term “Feedback Network (FBN)” refers to a circuit configuration that returns a portion of the output signal to the input. The FBN is used to regulate system behavior, improve stability, and control gain by dynamically adjusting the signal response.

The term “Feedforward Network (FFN)” refers to a circuit configuration that directly influences the output without relying on feedback. The FFN is used for phase correction, noise reduction, and enhancing signal integrity by applying a predetermined transformation to the input signal.

The term “Complementary Metal-Oxide-Semiconductor (CMOS)” refers to a semiconductor technology used in digital and analog circuit design. CMOS technology is known for its low power consumption, high noise immunity, and widespread use in integrated circuits for computing and communication systems.

The term “Photoplethysmography (PPG)” refers to an optical technique used to measure blood volume changes in tissue. The PPG method detects variations in light absorption due to pulsatile blood flow and is commonly applied in biomedical and wearable health-monitoring devices.

The term “Low-Pass Filter (LPF)” refers to a circuit that allows low-frequency signals to pass while attenuating high-frequency components. The LPF is widely used in signal conditioning applications to reduce noise and preserve essential signal characteristics.

The term “Photodetector (PD)” refers to an optoelectronic sensor that converts incident light into an electrical signal. The PD is commonly used in optical communication systems, biomedical devices, and imaging applications to detect light intensity variations.

The term “Low-Noise Amplifier (LNA)” refers to an electronic amplifier designed to amplify weak signals while minimizing additional noise. The LNA is essential in highly sensitive applications, such as wireless communication, radar systems, and biomedical sensing.

The present disclosure provides an apparatus for efficiently transferring electrical current using a voltage-controlled current source (VCCS) and phase-shifting networks. The apparatus includes a VCCS component with input terminals that receive an input voltage signal, a feedback network connected to the output of the VCCS and the input terminal, and a feedforward network connected to the output of the VCCS to produce an output current signal. The feedback network performs a phase-shifting operation on the voltage signal and feeds a phase-shifted voltage back to the input terminal, while the feedforward network applies another phase shift to control the gain of the output current signal based on its impedance.

An objective of the disclosure is to regulate the gain of the output current signal while maintaining stability and efficiency in current transfer. The present disclosure achieves the objective by configuring the feedback and feedforward networks with multiple parallel inverter components. The gain of the output current signal is determined based on the ratio of inverter components in the feedback and feedforward networks. Additionally, the present disclosure ensures a lower impedance at the first input terminal than the output terminal, facilitating improved current transfer characteristics.

The present disclosure adjusts impedance values within the feedback and feedforward networks to achieve a unity gain configuration. The method includes increasing the resistance in the feedback network and the open-loop gain of the VCCS to reduce impedance at the first input terminal while increasing the resistance in the feedforward network to raise the impedance at the output terminal. The present disclosure dynamically optimizes the total output impedance of the VCCS based on the combined impedance of both networks.

The present disclosure addresses challenges related to maintaining a stable and controlled current gain, ensuring efficient voltage feedback, and minimizing impedance mismatches in electrical circuits. The apparatus is designed to be integrated into various applications, including biomedical devices, where precise current control is essential. The present disclosure enhances circuit performance by effectively regulating current flow and gain through a structured feedback-feedforward mechanism.

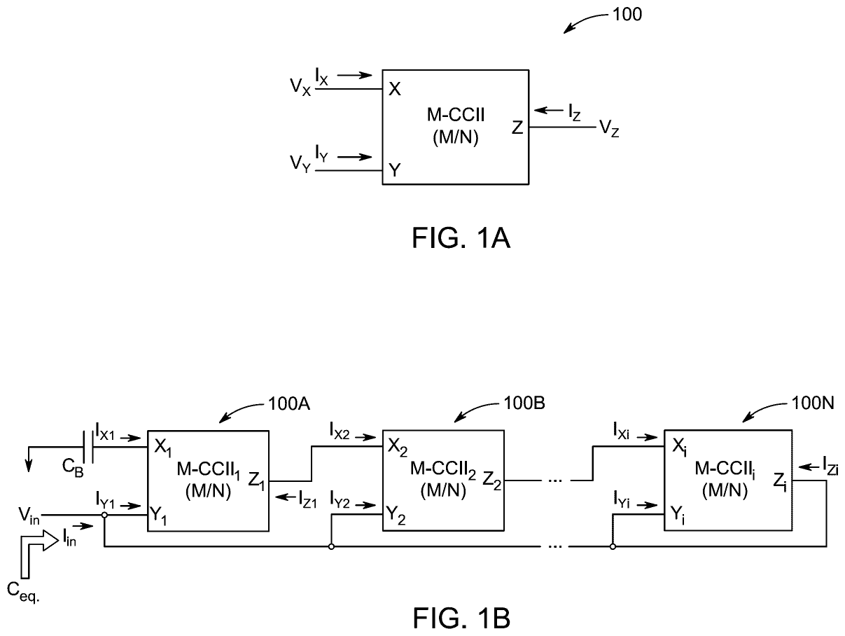

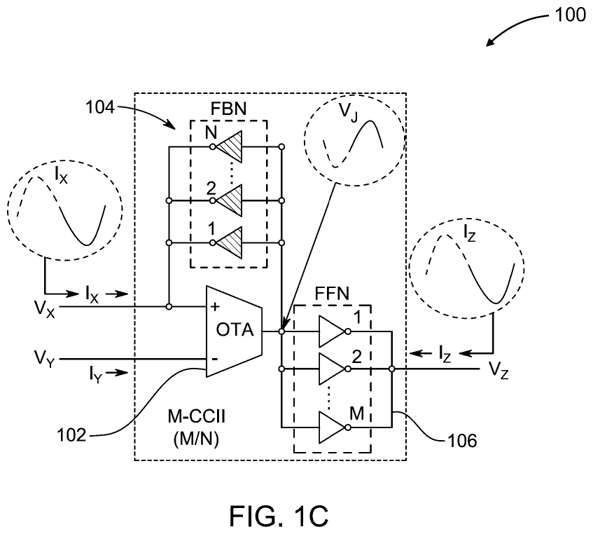

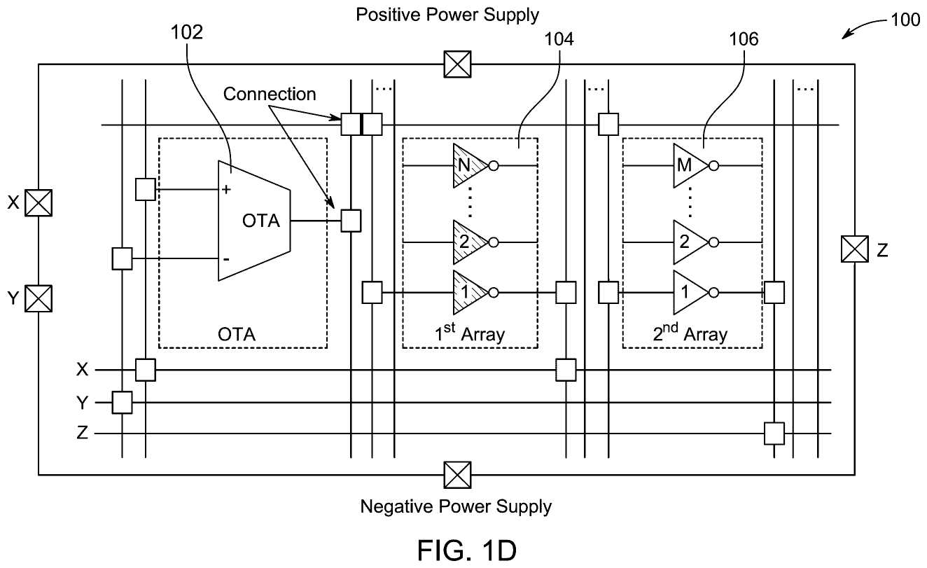

FIG. 1A-FIG. 1D illustrates an exemplary representation of an apparatus having a circuitry for transferring electrical current, according to one or more aspects of the present disclosure.

The apparatus 100 comprises a voltage-controlled current source (VCCS) component 102, a feedback network 104, and a feedforward network 106.

FIG. 1A illustrates an exemplary representation of a symbol of an apparatus 100 having circuitry for transferring electrical current, according to an embodiment of the present invention. FIG. 1A includes the apparatus 100 that may also be referred to as a Modified Current Conveyor Second Generation (M-CCII) circuit having a circuitry for transferring electrical current, according to one or more aspects of the present disclosure. FIG. 1B illustrates an exemplary representation of a conceptual building block of the apparatus 100 having circuitry for transferring electrical current, according to an embodiment of the present disclosure. FIG. 1C illustrates an exemplary representation of a circuit architecture of the apparatus 100 having circuitry for transferring electrical current, according to an embodiment of the present disclosure.

The apparatus 100 comprises a voltage-controlled current source (VCCS) component 102 that may also be referred to as a single transconductance amplifier (OTA), a feedback network FBN 104, and a feedforward network FFN 106. As shown in FIG. 1A, the apparatus 100 functions as a three-terminal device with input terminals X and Y, where the input voltages and currents are denoted as V_{X}, V_{Y}, I_{X}, and I_{Y}, respectively. The output terminal Z carries the output voltage V_{Z} and output current I_{Z}.

In an embodiment, the circuitry comprises a voltage-controlled current source VCCS component 102. The VCCS component 102 includes a pair of input terminals, wherein an input voltage signal is applied at a first input terminal of the pair of input terminals. The VCCS component 102 serves as the primary element for current generation based on the applied voltage, enabling efficient current transfer within the circuitry.

In an embodiment, the circuitry further comprises a feedback network FBN 104. The FBN 104 is connected to the output of the VCCS component 102 and the first input terminal. The FBN 104 is responsible for regulating the voltage gain of the apparatus by performing a phase-shifting operation on the voltage signal present at the output of the VCCS component 102. The phase-shifted voltage signal is then fed back to the first input terminal, thereby ensuring stable operation of the circuitry and maintaining desired electrical characteristics.

In an embodiment, the circuitry also includes a feedforward network FFN 106. The FFN 106 is connected to the output of the VCCS component 102 and is configured to produce an output current signal at an output terminal of the apparatus. The FFN 106 performs a phase-shifting operation on the voltage signal to generate a second phase-shifted voltage signal at the output terminal. The second phase-shifted voltage signal causes the output current signal to flow through the FFN 106. The FFN 106 further controls the specified gain of the output current signal over an input current signal at the first input terminal, and this control is based on an impedance of the FFN 106. In an embodiment, the apparatus 100 is configured to output a current with a specified gain that is proportional to the ratio of M to N.

FIG. 1B illustrates a conceptual building block of a resistorless capacitor multiplier implemented using a cascaded configuration of multiple apparatus 100 forming a system. In an embodiment, the system comprises a plurality of apparatus 100A-100N, wherein each apparatus 100A-100N is configured to receive an input current (I_{X}_{ᵢ}) at a first terminal (Xᵢ) and generate an output current (I_{Z}_{ᵢ}) at a second terminal (Zᵢ) based on a configurable current gain (M/N). Each apparatus 100A, 100B, 100N further includes a third terminal (Yᵢ) that maintains a voltage (V_{Y}_{ᵢ}) substantially equivalent to the voltage at the corresponding first terminal (Xᵢ). The system further includes a base capacitor (C_{B}), wherein the base capacitor is coupled to at least one of the apparatuses 100A-100N to facilitate capacitance multiplication.

In an embodiment, a cascaded arrangement of i or the plurality of apparatus 100A-100N results in an effective capacitance (C_{eq}) given by C_{eq}=(−M/N)¹C_{B}, thereby enabling substantial capacitance enhancement without requiring physically large capacitors. The absence of passive resistors in the configuration reduces overall power consumption and simplifies circuit integration, making the system particularly advantageous for low-frequency analog signal processing applications. Furthermore, by adjusting the current gain parameter (M/N), the system dynamically tunes the effective capacitance value, thereby providing enhanced configurability and adaptability in integrated circuit designs.

The invention leverages this resistorless capacitor multiplier to efficiently implement impedance converters and filter circuits based on current-mode processing, as depicted in FIG. 1C. The cascaded plurality of apparatus 100 can be utilized in applications such as biomedical signal processing, IoT devices, and analog filtering systems where large capacitance values are required but physical space is constrained.

In an embodiment, as shown in FIG. 1C, the apparatus 100 includes the voltage-controlled current source (VCCS) component 102 that may also be referred to as a single transconductance amplifier OTA 102, which serves as the core voltage-controlled current source VCCS of the apparatus 100. The OTA 102 is designed to function with CMOS-based inverter arrays that construct the FBN 104 and FFN 106. Precisely, the FBN 104 consists of N CMOS inverters, while the FFN 106 consists of M CMOS inverters.

Although the FFN 106 is connected between the output of the OTA 102 and its non-inverting terminal, the feedback loop functions as negative feedback due to the phase shift introduced by the CMOS inverters. The essential operation of the apparatus 100 is that the injected current I_{X} is converted into a compressed voltage at a joint voltage node V_{J}, with a 180° phase shift introduced by the FBN 104. The compressed voltage is then converted back into a current I_{Z} through the FFN 106. The resulting current I_{Z} is proportional to I_{X} by a factor of M/N, provided V_{Z} is equal to V_{X}.

In an embodiment, the FBN 104 contains a nonlinear element that may introduce distortion at V_{J}. However, this distortion is counteracted by the FFN 106 when both networks are precisely matched, ensuring accurate current transfer and impedance control.

In an embodiment, the apparatus 100 further comprises a gain control unit that adjusts the current gain of the apparatus 100 by modifying the transconductance values of the OTA 102. The gain control unit is configured to regulate the ratio of M to N in real time, thereby dynamically adapting the apparatus 100 to different operational conditions.

In an embodiment, the apparatus 100 also includes a bias stabilization circuit coupled to the OTA 108. The bias stabilization circuit ensures that the OTA 108 operates within its optimal transconductance range, preventing drift in current gain and enhancing the long-term reliability of the apparatus.

In an embodiment, the apparatus 100 is implemented with temperature compensation circuitry that counteracts temperature-induced variations in the performance of the OTA 102, FBN 104, and FFN 106. The temperature compensation circuitry ensures that the impedance and gain characteristics of the apparatus 100 remain stable across varying environmental conditions. In an embodiment, the characteristics of the apparatus 100 can be expressed as:

$$[ \begin{matrix}{I}_{z} \\ {V}_{x} \\ {I}_{y}\end{matrix} ] = [ \begin{matrix}0 & β & 0 \\ α & 0 & 0 \\ 0 & 0 & 0\end{matrix} ] [ \begin{matrix}{V}_{y} \\ {I}_{x} \\ {V}_{z}\end{matrix} ] \qquad ( 1 )$$

where β represents the current gain, and a represents the voltage gain. The impedance at the terminals X, Y, and Z—denoted as Z_{X}, Z_{Y}, and Z_{Z}, respectively—can be derived using small-signal modelling techniques.
Z_{X} is significantly small to ensure proper current sensing.
Z_{Y} is high due to the high open-loop gain of the OTA 102.
Z_{Z} is designed to be significant to maintain a stable output current source.

FIG. 1D illustrates another exemplary representation of a circuit architecture of the apparatus having circuitry for transferring electrical current, according to an embodiment of the present invention. FIG. 1D illustrates the operational transconductance amplifier (OTA) 102, the first array representing the feedback network (FBN) 104, and the second array representing the feedforward network (FFN) 106. FIG. 1D also depicts the input terminals X and Y, the output terminal Z, and the positive and negative power supply connections, indicating the general physical arrangement of the functional blocks of the apparatus 100.

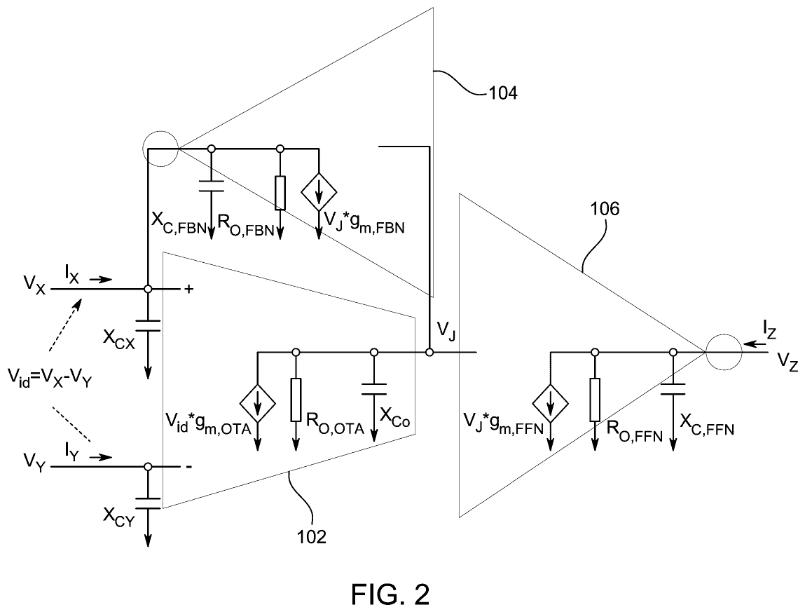

The non-ideal behavior model of the apparatus 100 can be examined by using the small signal equivalent circuit architecture shown in FIG. 2. FIG. 2 illustrates an exemplary representation of a small signal equivalent circuit, according to an embodiment of the present invention. Here, a and B can be expressed by equations (2) and (3), respectively. Regarding the impedance at the X, Y, and Z ports, Z_{X}, Z_{Y}, and Z_{Z}, can be derived as given in equations (4), (5), and (6), respectively.

$$α = \frac{g {m}_{m B N} * g {m}^{*} * {R}_{0} \vert \vert {X}_{C o}}{\frac{1}{{X}_{Cx} ‖ {X}_{C , FBN} ‖ {R}_{O , FBN}} + gm , {FBN}^{*} {gm}^{*} * {R}_{o} \vert \vert {X}_{Co}} \qquad ( 2 )$$

$$β = \frac{{I}_{Z}}{{I}_{X}} ≅ \frac{gm , FFN}{gm , FBN} \qquad ( 3 )$$

$${Z}_{X} = \frac{1}{\frac{1}{{X}_{CX} ‖ {X}_{C , FBN} ‖ {R}_{o , FBN}} + gm , {FBN}^{*} {gm}^{*} * {R}_{o} \vert \vert {X}_{Co}} \qquad ( 4 )$$

$${Z}_{Y} = \frac{1}{2 π {c}_{Y}} \qquad ( 5 )$$

$${Z}_{Z} = {X}_{C , F F N} \vert \vert {R}_{o , FFN} \qquad ( 6 )$$

where gₘ and Rₒ are the transconductance and the output resistance of the OTA 102, respectively;
g_{m,FBN} is the total transconductance of the feedback network,
g_{m,FFN} is the total transconductance of the feedforward network,
R_{O,FBN} is the total output resistor of the feedback network,
R_{O,FFN} is the total output resistor of the feedforward network,
X_{C,FBN} is the total output capacitive impedance of the feedback network 104,
X_{C,FFN} is the total output capacitive impedance of the feedforward network 106,
X_{Co} is the total output capacitive impedance of the OTA 102, including the input capacitive impedance of the FBN 104 and the FFN 106, and
X_{CX(Y)} is the input impedance at terminals X(Y) of the OTA 102, dependent on the length (L) and width (W) of input differential pairs MOSFET of the OTA 102.

Further, g_{m,FBN} (FFN) equals N(M) times of the transconductance of an inverter in the FFN 106, R_{O,FBN(FFN)} equals the reciprocal of N(M) of the output impedance of an inverter in the FBN (FFN). Also, X_{C,FBN(FFN)} equals the reciprocal of N(M) of the capacitive impedance of an inverter in the FBN (FFN). C_{Y} is the total capacitance at the terminal Y.

To force α to be unity, R_{O,FBN} should be significantly large. In addition, β is a ratio of M to N if we keep the inverters perfectly matched. Since the X terminal senses a current signal, its impedance should be significantly small by increasing both the R_{0,FBN} and the open loop gain of the OTA 102, (gₘ*Rₒ∥X_{Co}). Moreover, the Z terminal acts as a current source, its impedance should be large so, R_{o,FFN} should be designed large. It is noted that the proposed circuit architecture provides flexibility to build a current conveyor circuit with a current gain of more or less than unity.

In an embodiment, the gain of the apparatus 100 can be configured by adjusting the impedance properties of the FBN 104 and FFN 106. To achieve a unity gain condition, the following criteria should be met:
The open-loop gain of the OTA 102 should be significantly large.
The current gain (β) should be exactly M/N if the inverters are perfectly matched.
The impedance at the X terminal (Z_{X}) should be minimized to enhance current sensing accuracy.
The impedance at the Z terminal (Z_{Z}) should be maximized for stable current sourcing.

In an embodiment, the OTA 102 is realized using a Miller-compensated OTA 102 and a CMOS inverter-based structure to enhance voltage and current gain accuracy. The bias circuit provides the reference current IREF to stabilize operation. The CMOS inverter structure is optimized to reduce static current consumption while ensuring high performance.

In an embodiment, the apparatus 100 is further configured to provide noise immunity by incorporating a differential input structure. The differential input structure allows the apparatus to reject common-mode noise signals, ensuring reliable operation in environments with electrical interference.

In an embodiment, the apparatus 100 includes a calibration mechanism that periodically adjusts the transconductance values of the OTA 108 based on feedback measurements. This ensures that the apparatus maintains optimal performance despite variations in operating conditions.

In an embodiment, the circuitry is configured to be integrated into a biomedical device. The integration of the apparatus into the biomedical device facilitates precise control over current flow, which is critical for applications such as medical signal processing, bio-impedance measurement, and neural stimulation.

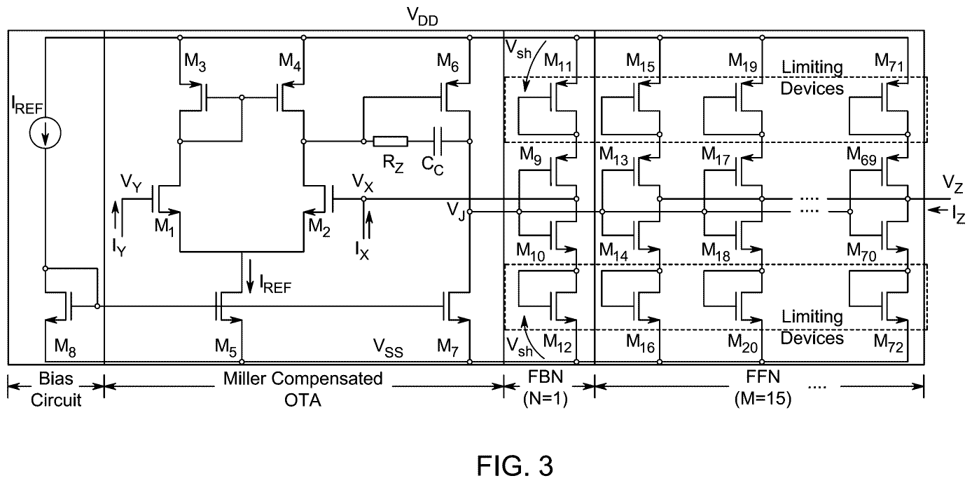

In an embodiment, several CMOS-based structures can be utilized to realize the OTA 102 and CMOS inverters of the apparatus 100, thereby enhancing the accuracy of voltage and current gain while increasing the output current capabilities with low power consumption. As shown in FIG. 3, a circuit architecture of an apparatus 100 with β=(15/1) is illustrated, with a configuration of M=15 and N=1, and the apparatus 100 is implemented using a Miller-compensated OTA, a CMOS inverter, and a bias circuit.

In an embodiment, the Miller-compensated OTA is selected due to its ability to drive large capacitive loads, extending up to several picofarads. This property ensures stable performance in applications requiring precise current transfer. Additionally, a CMOS inverter is adapted to minimize static current consumption by incorporating NMOS and PMOS transistors as limiting current devices. Furthermore, a bias circuit is included to provide the reference current (IREF) necessary for stable operation.

In an embodiment, the Miller-compensated OTA consists of multiple transistor stages designed to optimize stability and phase margin. The first stage includes transistors M1 and M2, forming a PMOS differential input pair, with M3 and M4 as active loads. A tail current source (M5) provides the necessary current for the differential pair. The second stage, comprising transistors M6 and M7, operates as a common-source amplifier, delivering the required voltage gain. Both stages are biased by M8, which supplies the reference current (IREF) from the bias circuit. The compensation network, including resistor Rz and capacitor Cc, is implemented to enhance stability, ensuring an improved phase margin when driving capacitive loads.

In an embodiment, the feedback network (FBN) 104 is realized using a single modified CMOS inverter, consisting of transistors M9-M12. The feedforward network (FFN) 106 is implemented with fifteen modified CMOS inverters, incorporating transistors M13-M72, which include additional limiting current devices. This structure ensures accurate current scaling with a current gain factor of β=M/N=15/1.

As illustrated in FIG. 3, the circuit architecture optimizes current transfer efficiency while maintaining low power consumption and high stability, making it suitable for applications requiring precise electrical current regulation.

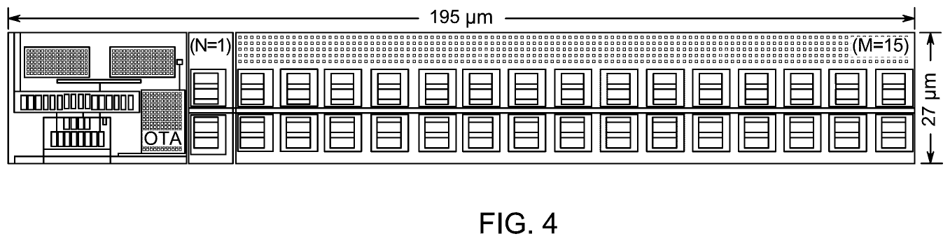

In an embodiment, the proposed apparatus 100 has been designed and simulated using TSMC 0.18 μm CMOS technology with a single power supply (VDD) of 1.8 V. As illustrated in FIG. 4, the layout of the M-CCII (15/1) has been designed using Virtuoso layout editor tools, occupying a compact silicon area of 195 μm×27 μm.

Current-mode circuits play a crucial role in modern analog signal processing due to their high-speed operation, low voltage requirements, and superior performance in low-power applications. Among these, the apparatus 100 may be used for various analog applications, including filters, oscillators, and amplifiers. However, conventional CCII architectures often have limitations in terms of linearity, bandwidth, impedance matching, and power efficiency, which restrict their applicability in high-performance systems.

To address these challenges, the present disclosure presents the apparatus 100 of type II (M-CCII) with a gain factor of 15/1. The apparatus 100 is designed using TSMC 0.18 μm CMOS technology and operates with a single supply voltage of 1.8 V.

To validate the performance of the apparatus 100, extensive pre-layout and post-layout simulations have been conducted under typical (TT) and extreme process-voltage-temperature (PVT) variations. Additionally, Monte Carlo (MC) analysis has been performed to assess the statistical robustness of the circuit against process and mismatch variations. The simulation results demonstrate that the proposed apparatus 100 outperforms existing prior arts regarding bandwidth, power efficiency, and impedance characteristics, making the apparatus suitable for modern analog signal processing applications.

The following sections present a detailed discussion of the simulation results, including voltage gain (a) and current gain (B) performance, transient analysis, impedance characteristics of terminals X, Y, and Z, Monte Carlo (MC) statistical analysis, Process-Voltage-Temperature (PVT) variations, and comparative benchmarking with the proposed apparatus 100.

In an embodiment, the apparatus 100 has been designed and simulated using TSMC 0.18 μm CMOS technology with a single power supply (VDD) of 1.8 V. FIG. 4 illustrates another exemplary representation of a layout of the apparatus 100 with b=(15/1) having circuitry for transferring electrical current, according to an embodiment of the present invention. As illustrated in FIG. 4, the layout of the apparatus 100 has been designed using Virtuoso layout editor tools, occupying a compact silicon area of 195 μm×27 μm.

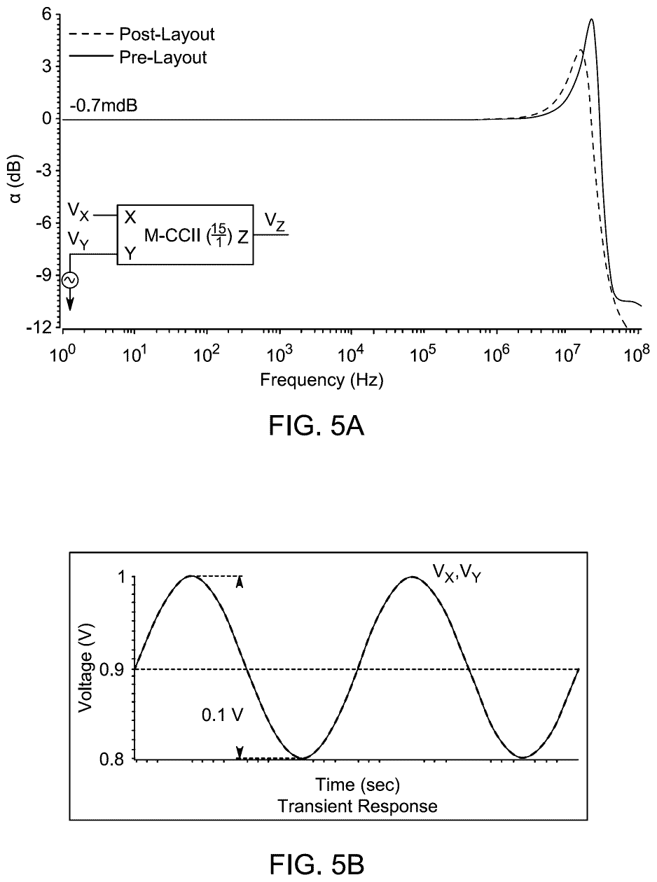

To evaluate the performance of the apparatus 100, the process, supply voltage, and temperature (PVT) conditions are set to typical-typical (TT), 1.8 V, and 27° C., respectively. The pre-layout and post-layout simulation results of the voltage gain (a) are depicted in FIG. 5A and FIG. 5B. FIG. 5A and FIG. 5B illustrate a graphical representation of pre- and post-layout simulation results of a voltage gain (a), according to an embodiment of the present invention. The frequency response analysis reveals that the voltage gain bandwidth (α_{BW}) reaches 2.8 MHz, with a DC gain of −0.7 mdB. Furthermore, the transient response demonstrates that V_{X} accurately tracks V_{Y} when subjected to a sinusoidal input signal of 0.1 V amplitude and 10 KHz frequency.

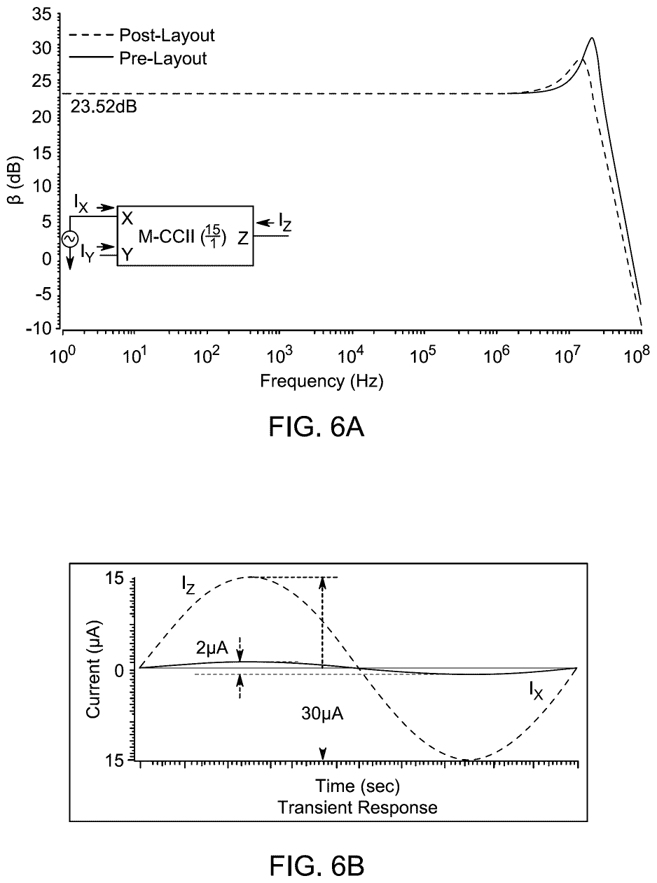

In an embodiment, the current gain (B) exhibits a bandwidth (BBW) of 32.6 MHz, with a DC gain of 23.52 dB, as illustrated in FIG. 6A and FIG. 6B. FIG. 6A and FIG. 6B illustrates a graphical representation of pre- and post-layout simulation results of a voltage gain (α), according to an embodiment of the present invention. In transient analysis, the injected current (I_{X}) with an amplitude of 2 μA peak-to-peak at 10 kHz is amplified by a factor of 15, demonstrating the expected current gain. Moreover, when applying a sinusoidal input current of 100 nA peak at 100 Hz, the total harmonic distortion (THD) is measured at 1.86%, indicating excellent linearity performance.

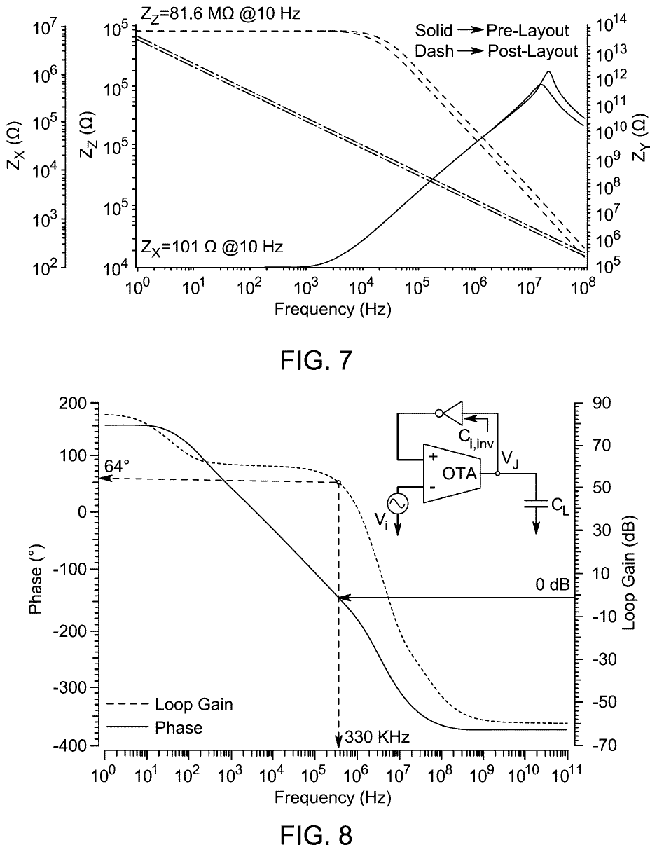

FIG. 7 illustrates a graphical representation of impedances at X, Y, and Z terminals of the apparatus 100 with b=(15/1) having circuitry for transferring electrical current, according to an embodiment of the present invention. As shown in FIG. 7, the impedance characteristics at the X, Y, and Z terminals of the proposed apparatus are analyzed through pre-layout and post-layout simulations. The results indicate that:
Z_{X} exhibits a low impedance of 101Ω at low frequencies, allowing efficient current sensing.
Z_{Z} reaches a high impedance of 81.6 MΩ, ensuring effective current delivery to the load.
Z_{Y} is characterized by an input capacitance (C_{Y}) of 4 fF.

### Monte Carlo (MC) Analysis

In an embodiment, the MC simulations are performed at 27° C. and 1.8 V to assess performance variations due to process and mismatch effects. A total of 1000 MC runs ensure statistical evaluation, targeting a yield within +36. The MC setup utilizes a random statistical distribution model to vary all NMOS and PMOS transistor parameters, simulating real-world manufacturing variability. The coefficient of variance (CV=(σ/μ)×100%) quantifies the deviation between the mean value (μ) and standard deviation (σ) of key performance parameters.

Table 1 presents the MC or prior art simulation results for the apparatus 100 and a comparison with prior arts. The results demonstrate a significantly low CV, indicating robust performance and high manufacturability.

TABLE 1
Monte-Carlo (MC) Process and Mismatch Results With runs of 1000

| Ref. | Run | Parameter | μ | σ | CV [%] |
|---|---|---|---|---|---|
| Apparatus | 1000 | \|α\| (mdB) | 0.731 | 0.083 | 11.354 |
| (100) | | α_{BW}(MHz) | 2.86837 | 0.036 | 1.2550 |
| | | \|β\| (dB) | 23.5218 | 0.763μ | 3.2E−06 |
| | | β_{BW}(MHz) | 32.6 | 1.55 | 4.754 |
| | | Z_{X}(Ω) | 115.731 | 23.3 | 20.13 |
| | | Z_{Z}(MΩ) | 81.71 | 14.6 | 17.86 |
| | | C_{Y} (fF) | 4.0005 | 0.046 | 1.149 |
| IEEE'19 | 200 | \|α\| (mdB) | 4.017 | 11.916 | 296.63 |
| [10] | | \|β\| (mdB) | 14.2431 | 80.706 | 11.35 |

In an embodiment, the apparatus 100 is evaluated under PVT variations across:
Process corners: typical-typical (TT), fast-fast (FF), slow-slow (SS), fast-slow (FS), and slow-fast (SF).
Power supply levels: ±10% of nominal VDD (ranging from 1.62 V to 1.98 V).
Temperature range: −40° C. to 85° C.

Table 2 summarizes the worst-case scenarios of the apparatus 100 under multiple parameters. The results confirm that the circuit maintains stable performance despite variations, making the apparatus 100 suitable for practical fabrication.

TABLE 2
Process-Voltage-Temperature Results

| | | | Conditions | | |
|---|---|---|---|---|---|
| Parameter | | Value | Process | Voltage | Temperature |
| ¹\|α\| (μdB) | Min. | 605.83 | TT | 1.98 | −40 °C |
| | Max. | 1085.1 | SF | 1.62 | 85 °C |
| α_{BW}(MHz) | Min. | 0.302 | SS | 1.62 | −40 °C |
| | Max. | 9.694 | FF | 1.98 | 85 °C |
| ¹\|β\| (dB) | Min. | 23.521824 | FF | 1.98 V | −40 °C |
| | Max. | 23.521828 | SS | 1.62 V | 85 °C |
| β_{BW}(MHz) | Min. | 10.518 | SS | 1.62 V | −40 °C |
| | Max. | 43.465 | FF | 1.98 V | −40 °C |
| ¹Z_{X}(Ω) | Min. | 31.421 | TT | 1.98 | 85 °C |
| | Max. | 2414.2 | SS | 1.62 | −40 °C |
| ¹Z_{Z}(MΩ) | Min. | 13.6 | FF | 1.98 | 85 °C |
| | Max. | 1931.5 | SS | 1.62 | −40 °C |
| C_{Y} (fF) | Min. | 3.926 | SS | 1.98 | 85 °C |
| | Max. | 4.689 | FF | 1.62 | −40 °C |

In an embodiment, the performance of the apparatus 100 is benchmarked against recent prior arts, as summarized in Table 3.

TABLE 3
Performance of the apparatus and comparison with the known arts

| | | JLPEA′24 | SPIN′21 | ACSP′21 | MEJ′19 | IEEE′19 | MEJ′16 | AEU′12 | MEJ′11 |
|---|---|---|---|---|---|---|---|---|---|
| Parameter | Apparatus | [1] | [3] | [4] | [5] | [6] | [2] | [7] | [8] |
| Technology | 180 | 65 | 180 | 180 | 180 | 180 | 130 | 180 | 180 |
| [nm] | | | | | | | | | |
| V_{DD} [V] | 1.8 | 0.35 | 0.5 | 0.5 | 0.4 | 0.5 | 1.5 | 0.5 | 0.8 |
| P_{D} [μW] | 73.3 | 1 | 0.5 | 2.43 | 0.25 | 0.509 | 1500 | 30 | 64 |
| \|α\| [mdB] | 0.7 | 4.1 | 0.017 | 0.02 | 0.017 | 0.009 | 5 | 0.017 | 0 |
| α_{BW} | 2.8 | 1.33 | 0.081 | 0.072 | 0.011 | 0.0564 | 94 | 11 | 14 |
| [MHz] | | | | | | | | | |
| \|β\| [dB] | 32.6 | 2.1 | 0.01 | 0 | 0.035 | 0.009 | 0.13 | 0.035 | 0 |
| β_{BW}[MHz] | 32.6 | 2.13 | 1.38 | 0.072 | 0.082 | 0.578 | 99 | 10 | 13 |
| Z_{X} [Ω] | 101 | 1800 | 1210 | 7000 | 260 | 56000 | 200 | 260 | N/A |
| Z_{Z} [MΩ] | 81.6 | 7.46 | 6.53 | 2 | 0.133 | 94.7 | 0.56 | 0.1130 | 0.89 |
| C_{Y} [fF] | 4 | 106.1 | N/A | N/A | 100 | N/A | 10 | N/A | 117 |
| Silicon | 0.0052 | N/A | N/A | N/A | N/A | 0.0134 | 0.1568 | N/A | N/A |
| Area | | | | | | | | | |
| [mm²] | | | | | | | | | |
| ^{a}FOM | 18.6 | 2.22 | 0.223 | 0.0021 | 0.0035 | 0.063 | 6.301 | 3.65 | 2.84 |

### REFERENCES

[1] M. O. Shah, M. Caruso, and S. Pennisi, “0.35 V Subthreshold Bulk-Driven CMOS Second-Generation Current Conveyor,” Journal of Low Power Electronics and Applications, vol. 14, no. 36, pp. 1-12, 2024 (incorporated by reference in its entirety).
[2] A. Reda, M. F. Ibrahim, and. Farag, “Input-output Rail-to-Rail CMOS CCII for low voltage-low power applications,” Microelectronics Journal, vol. 48, pp. 60-75, 2016 (incorporated by reference in its entirety).
[3] A. Agrawal, M. Gupta and S. Kumari, “Design of Low Voltage Current Conveyor based on Bulk-driven Self-cascode approach,” Proceedings of the in 8^{th} SPIN, Noida, India, 2021, pp. 242-247 (incorporated by reference in its entirety).
[4] A. K. Gautam, T. Sharan, and P. Ne. Zou “DTMOS-Based Low-Voltage Low-Power CCII+ and Biquad Filter Using+0.25 V Supply,” Proceedings of the Advances in VLSI, Communication, and Signal Processing, India, 2021, pp. 271-289 (incorporated by reference in its entirety).
[5] M. Kumngern, “0.4 V fully differential current conveyor using multiple-input bulk-driven MOST technique,” Microelectronics Journal, vol. 90, pp. 96-104, 2019 (incorporated by reference in its entirety).
[6] F. Khateb, T. Kulej, and M. Kumngern, “0.3V Bulk-Driven Current Conveyor,” IEEE Access, vol. 7, pp. 65122-65128, 2019 (incorporated by reference in its entirety).
[7] G. Raikos, S. Vlassis, and C. Psychalinos, “0.5 V bulk-driven analog building blocks,” International Journal of Electronics and Communications, vol. 66, pp. 920-927, 2012 (incorporated by reference in its entirety).
[8] F. Khateb, N. Khatib, D. Kubanek, “Novel low-voltage low-power high-precision CCIIF based on bulk-driven folded cascode OTA,” Microelectronics Journal, vol. 42, pp. 622-631, 2011 (incorporated by reference in its entirety).

The key parameters, including voltage gain (a), current gain (B), bandwidth, power consumption, impedance values, and capacitance, are compared with prior arts. The results highlight that the apparatus 100 achieves:
Superior voltage and current gain-bandwidth product.
Lower power consumption compared to existing designs.
Higher impedance at the Z terminal for effective current delivery.
Compact silicon area of 0.0052 mm², demonstrating high integration efficiency.

Additionally, the figure of merit (FOM) is calculated using:

$${}^{a} FOM = \frac{\vert α \vert * {α}_{BW} [ MHz ] * \vert β \vert * {σ}_{BW} [ MHz ]}{{P}_{D} [ μ W ]}$$

where PD represents power consumption. The results indicate that the apparatus 100 provides a significant improvement in overall performance, making the apparatus 100 highly efficient for various analog signal processing applications.

FIG. 8 illustrates the loop gain and phase response of the apparatus 100, evaluating its stability characteristics. In an embodiment, the loop gain (indicated by the blue curve) and phase response (indicated by the red curve) are analyzed to determine the stability margins of the circuit. The phase margin, measured at the 0 dB crossover frequency, is 64°, ensuring adequate stability of the circuit. The unity-gain bandwidth is approximately 330 kHz, as indicated by the intersection of the loop gain curve with the 0 dB reference line.

In an embodiment, the feedback network (FBN) 104 is designed to mitigate variations in V_{X} and V_{Y} within a range of 65% of the power supply voltage, thereby maintaining stability. The number of M inverters in the system are constrained by the relation:

$$M \leq \frac{{C}_{L}}{{C}_{i , inv}} + 1 - N$$

where C_{L} represents the total capacitive load of the Operational Transconductance Amplifier (OTA), and C_{i,inv} denotes the input capacitance of a single CMOS inverter.

As depicted in FIG. 8, increasing C_{L}, which is a function of (M+N−1)×C_{i,inv}, significantly degrades the phase margin, leading to potential instability. A higher capacitive load extends the dominant pole's time constant, reducing the circuit's response speed and increasing susceptibility to oscillations. Therefore, the optimal selection of M and N is necessary to maintain stable operation while achieving the desired capacitance multiplication.

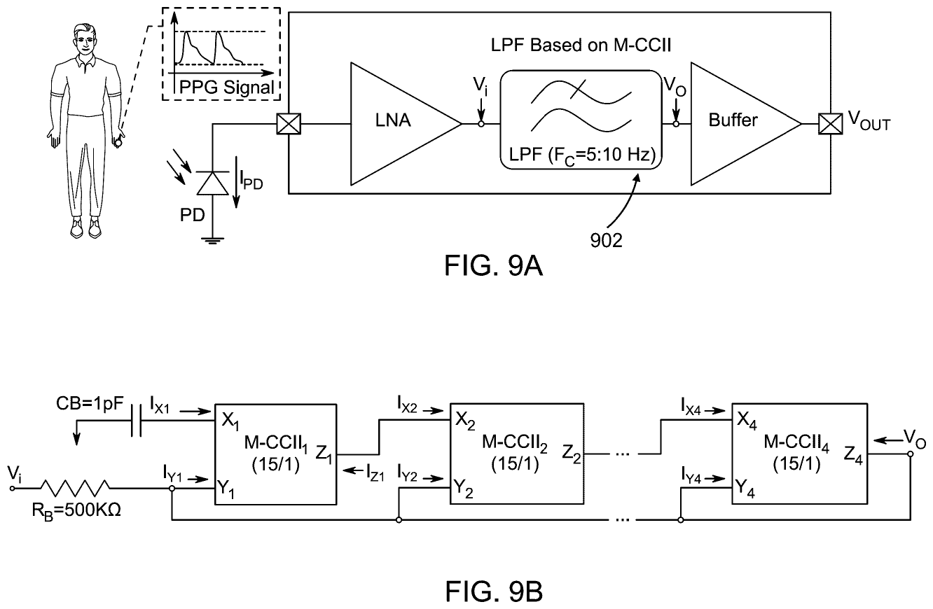

FIG. 9A and FIG. 9B illustrates an application of the apparatus 100 or the M-CCII circuit in a Photo Plethysmo Graphy (PPG) signal processing system, demonstrating capability of the apparatus 100 to maintain a steady current or achieve a specified current gain in biomedical signal processing. In an embodiment, the M-CCII-based low-pass filter (LPF) is implemented within a PPG sensor front-end to enhance signal integrity by suppressing high-frequency noise while preserving essential signal components.

FIG. 9A depicts a conceptual block diagram of the PPG sensor system. In an embodiment, the system comprises a photodetector (PD) that captures the PPG signal by detecting optical variations and converting them into a corresponding photocurrent (IPD). The low-noise amplifier (LNA) amplifies the weak signal before passing it to the M-CCII-based LPF 902, which operates within a cutoff frequency range of approximately 5-10 Hz. The LPF removes undesired high-frequency noise while maintaining the fundamental PPG waveform. The filtered signal is then fed into a buffer stage before reaching the output terminal (V_{OUT}).

FIG. 9B illustrates the internal structure of the apparatus 902 including the M-CCII-based LPF, which is composed of multiple cascaded M-CCII blocks (100a, 100b, . . . 100n) along with a capacitor (C_{B}) and a resistor (R_{B}). In an embodiment, the cascaded configuration of M-CCII circuits (each configured with a gain factor M/N=15/1) effectively achieves capacitor multiplication, enabling the emulation of a significantly larger capacitance from a smaller base capacitor. For example, with C_{B}=1 pF, the effective capacitance can be expanded up to 50 nF, allowing a corner frequency of approximately 6.4 Hz when coupled with R_{B}=500 kΩ. The configuration ensures the suppression of interference noise while maintaining the integrity of the PPG signal.

FIG. 9A and FIG. 9B demonstrate the applicability of the apparatus 100 in biomedical sensors and other systems requiring precise current control. By leveraging capacitor multiplication and low-power filtering, the M-CCII-based LPF enhances PPG signal processing, ensuring accurate and efficient bio signal acquisition.

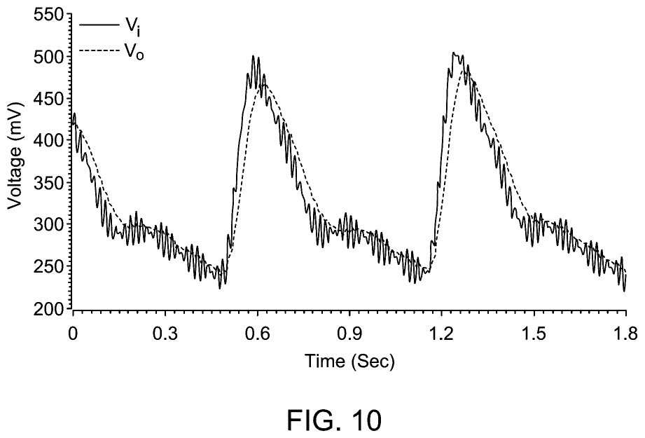

FIG. 10 illustrates the performance of the M-CCII-based low-pass filter (LPF) in processing photoplethysmographic (PPG) signals, demonstrating its effectiveness in reducing high-frequency noise components while preserving essential signal characteristics.

As depicted in FIG. 10, the input PPG signal (Vᵢ) exhibits high-frequency noise artifacts, which can arise from motion interference and ambient signal fluctuations. In contrast, the output signal (Vₒ), processed through the M-CCII-based LPF, shows a smoothened waveform, effectively eliminating unwanted noise while maintaining the primary PPG signal integrity.

This result underscores the efficacy of the M-CCII-based design in achieving precise and low-power signal filtering, making it an ideal solution for biomedical applications such as wearable health monitoring devices and bio signal acquisition systems.

Further in an embodiment, the apparatus 100 is implemented using TSMC 180 nm CMOS technology and is configured to achieve high accuracy and low power consumption. The apparatus 100 includes a current conveyor circuit that ensures minimal voltage gain error of 0.7 mdB and current gain error of 25 μdB, enabling precise analog signal processing. Additionally, the apparatus 100 is designed to operate with a power consumption of 73 μW, making it suitable for low-power applications. The compact design of the apparatus 100 occupies a silicon area of 0.0052 mm², optimizing its integration within semiconductor devices. Furthermore, the apparatus 100 demonstrates consistent performance across pre-layout and post-layout simulations, ensuring design reliability and manufacturability. The evaluation based on the Figure of Merit (FOM) establishes that the apparatus 100 outperforms the prior arts in terms of voltage and current gain-bandwidth efficiency relative to power consumption, making it a superior solution for high-performance analog circuits.

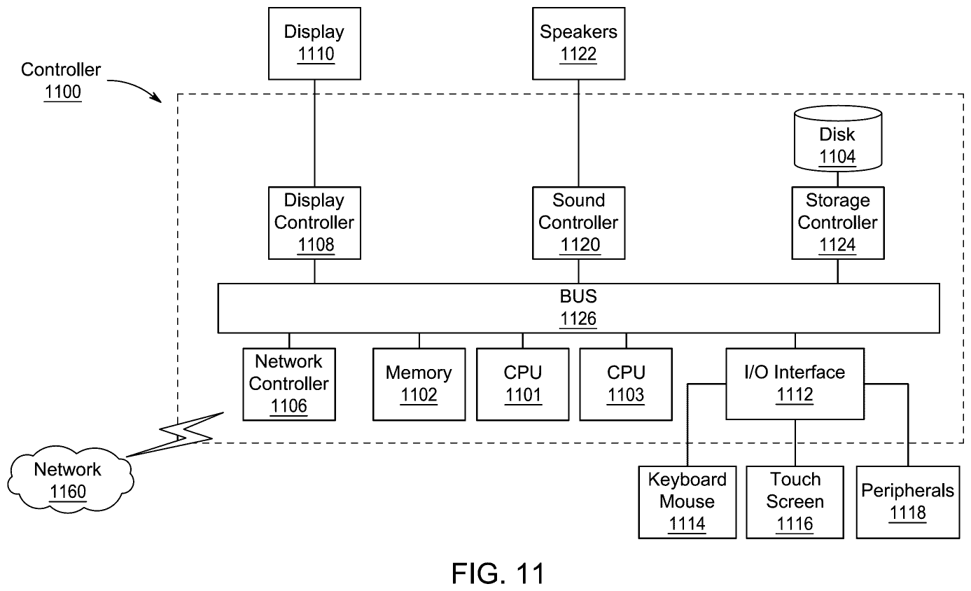

Next, further details of the hardware description of the computing environment of FIG. 1A-1D or 9A according to exemplary embodiments is described with reference to FIG. 11.

In FIG. 11, a controller 1100 is described as representative of a computing device that implements circuitry for transferring electrical current of FIG. 1C-FIG. 1D. The computing device includes a Central Processing Unit (CPU) 1101 which performs the processes described above/below. The process data and instructions may be stored in a memory 1102. These processes and instructions may also be stored on a storage medium disk 1104 such as a Hard Disk Drive (HDD) or a portable storage medium or may be stored remotely.

Further, the claims are not limited by the form of the computer-readable media on which the instructions of the inventive process are stored. For example, the instructions may be stored on Compact Disks (CDs), Digital Versatile Discs (DVDs), in a Flash memory, a Random Access Memory (RAM), a Read-Only Memory (ROM), a Programmable Read-Only Memory (PROM), an Erasable Programmable Read-Only Memory (EPROM), an Electrically Erasable Programmable Read-Only Memory (EEPROM), a hard disk or any other information processing device with which the computing device communicates, such as a server or a computer.

Further, the claims may be provided as a utility application, background daemon, or component of an operating system, or combination thereof, executing in conjunction with the CPU 1101, a CPU 1103 and an operating system such as a Microsoft Windows 7, a Microsoft Windows 10, a UNIX, a Solaris, a LINUX, an Apple MAC-OS and other systems known to those skilled in the art.

The hardware elements in order to achieve the computing device may be realized by various circuitry elements, known to those skilled in the art. For example, CPU 1101 or CPU 1103 may be a Xenon or Core processor from Intel of America or an Opteron processor from AMD of America, or may be other processor types that would be recognized by one of ordinary skill in the art. Alternatively, the CPU 1101, 1103 may be implemented on an FPGA, ASIC, PLD or using discrete logic circuits, as one of ordinary skilled in the art would recognize. Further, CPU 1101, 1103 may be implemented as multiple processors cooperatively working in parallel to perform the instructions of the inventive processes described above.

The computing device in FIG. 11 also includes a network controller 1106, such as an Intel Ethernet PRO network interface card from Intel Corporation of America, for interfacing with network 1160. As can be appreciated, the network 1160 can be a public network, such as the Internet, or a private network such as an LAN or WAN network, or any combination thereof and can also include PSTN or ISDN sub-networks. The network 1160 can also be wired, such as an Ethernet network, or can be wireless such as a cellular network including EDGE, 3G and 4G wireless cellular systems. The wireless network can also be WiFi, Bluetooth, or any other wireless form of communication that is known.

The computing device further includes a display controller 1108, such as a NVIDIA GeForce GTX or Quadro graphics adaptor from NVIDIA Corporation of America for interfacing with display 1110, such as a Hewlett Packard HPL2445w LCD monitor. A general purpose I/O interface 1112 interfaces with a keyboard and/or mouse 1114 as well as a touch screen panel 1116 on or separate from display 1110. General purpose I/O interface also connects to a variety of peripherals 1118 including printers and scanners, such as an OfficeJet or DeskJet from Hewlett Packard.

A sound controller 1120 is also provided in the computing device such as Sound Blaster X-Fi Titanium from Creative, to interface with speakers/microphone 1122 thereby providing sounds and/or music.

The general-purpose storage controller 1124 connects the storage medium disk 1304 with communication bus 1126, which may be an ISA, EISA, VESA, PCI, or similar, for interconnecting all of the components of the computing device. A description of the general features and functionality of the display 1110, keyboard and/or mouse 1114, as well as the display controller 1108, storage controller 1124, network controller 1106, sound controller 1120, and general purpose I/O interface 1112 is omitted herein for brevity as these features are known.

The exemplary circuit elements described in the context of the present disclosure may be replaced with other elements and structured differently than the examples provided herein. Moreover, circuitry configured to perform features described herein may be implemented in multiple circuit units (e.g., chips), or the features may be combined in circuitry on a single chipset, as shown on FIG. 11.

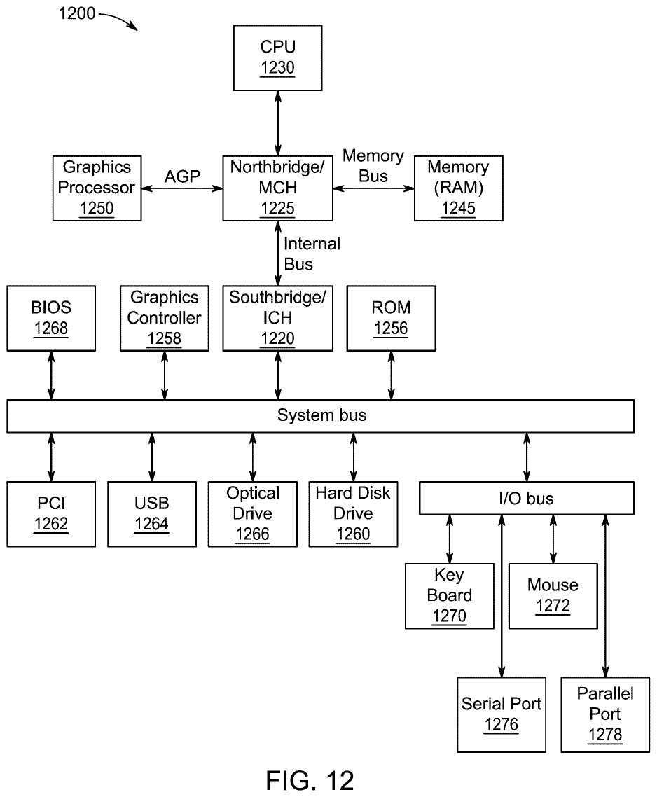

FIG. 12 shows a schematic diagram of a data processing system, according to certain embodiments, for performing the functions of the exemplary embodiments. The data processing system is an example of a computer in which code or instructions implementing the processes of the illustrative embodiments may be located.

In FIG. 12, data processing system 1200 employs a hub architecture including a north bridge and memory controller hub (NB/MCH) 1225 and a south bridge and input/output (I/O) controller hub (SB/ICH) 1220. The central processing unit (CPU) 1230 is connected to NB/MCH 1225. The NB/MCH 1225 also connects to the memory 1245 via a memory bus and connects to the graphics processor 1250 via an accelerated graphics port (AGP). The NB/MCH 1225 also connects to the SB/ICH 1220 via an internal bus (e.g., a unified media interface or a direct media interface). The CPU Processing unit 1230 may contain one or more processors and even may be implemented using one or more heterogeneous processor systems.

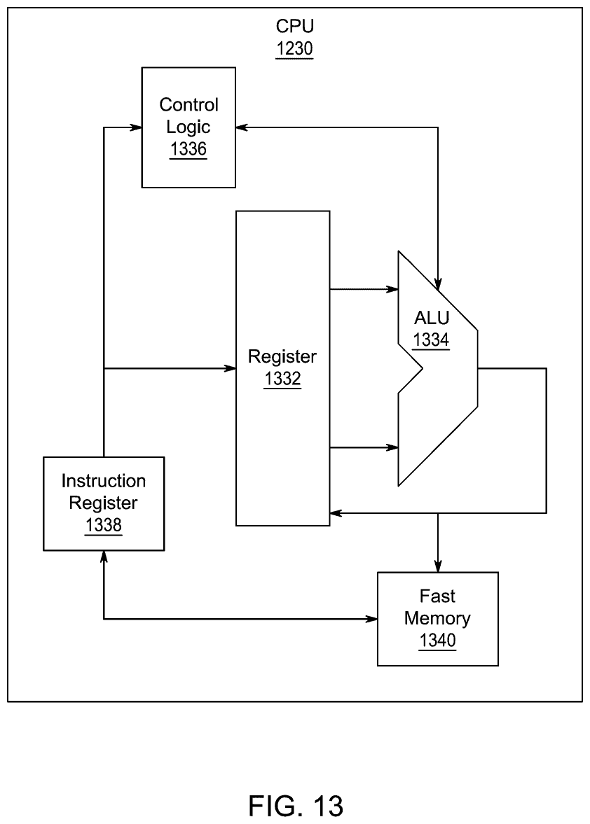

For example, FIG. 13 shows one implementation of CPU 1230. In one implementation, the instruction register 1332 retrieves instructions from the fast memory 1340. At least part of these instructions is fetched from the instruction register 1332 by the control logic 1336 and interpreted according to the instruction set architecture of the CPU 1230. Part of the instructions can also be directed to the register 1332. In one implementation the instructions are decoded according to a hardwired method, and in another implementation the instructions are decoded according to a microprogram that translates instructions into sets of CPU configuration signals that are applied sequentially over multiple clock pulses. After fetching and decoding the instructions, the instructions are executed using the arithmetic logic unit (ALU) 1334 that loads values from the register 1332 and performs logical and mathematical operations on the loaded values according to the instructions. The results from these operations can be feedback into the register and/or stored in the fast memory 1340. According to certain implementations, the instruction set architecture of the CPU 1230 can use a reduced instruction set architecture, a complex instruction set architecture, a vector processor architecture, a very large instruction word architecture. Furthermore, the CPU 1230 can be based on the Von Neuman model or the Harvard model. The CPU 1230 can be a digital signal processor, an FPGA, an ASIC, a PLA, a PLD, or a CPLD. Further, the CPU 1230 can be an x56 processor by Intel or by AMD; an ARM processor, a Power architecture processor by, e.g., IBM; a SPARC architecture processor by Sun Microsystems or by Oracle; or other known CPU architecture.

Referring again to FIG. 12, the data processing system 1200 can include that the SB/ICH 1220 is coupled through a system bus to an I/O Bus, a read only memory (ROM) 1256, universal serial bus (USB) port 1264, a flash binary input/output system (BIOS) 1268, and a graphics controller 1258. PCI/PCIe devices can also be coupled to SB/ICH 1220 through a PCI bus 1262.

The PCI devices may include, for example, Ethernet adapters, add-in cards, and PC cards for notebook computers. The Hard disk drive 1260 and CD-ROM666 can use, for example, an integrated drive electronics (IDE) or serial advanced technology attachment (SATA) interface. In one implementation the I/O bus can include a super I/O (SIO) device.

Further, the hard disk drive (HDD) 1260 and optical drive 1266 can also be coupled to the SB/ICH 1220 through a system bus. In one implementation, a keyboard 1270, a mouse 1272, a parallel port 1278, and a serial port 1276 can be connected to the system bus through the I/O bus. Other peripherals and devices that can be connected to the SB/ICH 1220 using a mass storage controller such as SATA or PATA, an Ethernet port, an ISA bus, a LPC bridge, SMBus, a DMA controller, and an Audio Codec.

Moreover, the present disclosure is not limited to the specific circuit elements described herein, nor is the present disclosure limited to the specific sizing and classification of these elements. For example, the skilled artisan will appreciate that the circuitry described herein may be adapted based on changes on battery sizing and chemistry or based on the requirements of the intended back-up load to be powered.

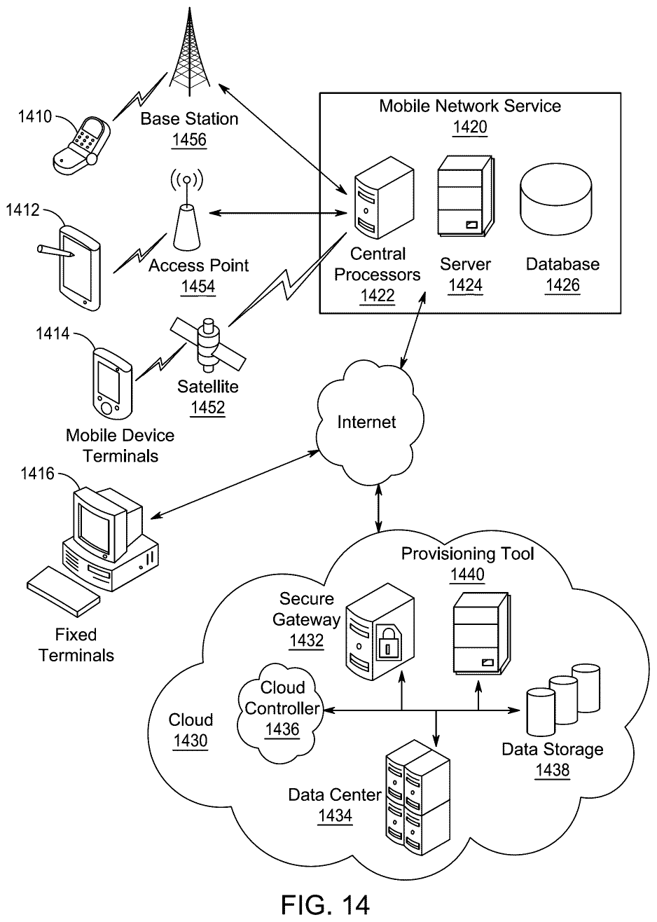

The functions and features described herein may also be executed by various distributed components of a system. For example, one or more processors may execute these system functions, wherein the processors are distributed across multiple components communicating in a network. The distributed components may include one or more client and server machines, which may share processing, as shown by FIG. 14, in addition to various human interface and communication devices (e.g., display monitors, smart phones, tablets, personal digital assistants (PDAs)). The network may be a private network, such as a LAN or WAN, or may be a public network, such as the Internet. Input to the system may be received via direct user input and received remotely, either in real-time or as a batch process. Additionally, some aspects of the present disclosures may be performed on modules or hardware not identical to those described. Accordingly, other aspects of the present disclosures are within the scope that may be claimed. More specifically, FIG. 14 illustrates client devices including smart phone 1411, tablet 1412, mobile device terminal 1414 and fixed terminals 1416. These client devices may be commutatively coupled with a mobile network service 1420 via base station 1456, access point 1454, satellite 1452 or via an internet connection. Mobile network service 1420 may comprise central processors 1422, server 1424 and database 1426. Fixed terminals 1416 and mobile network service 1420 may be commutatively coupled via an internet connection to functions in cloud 1430 that may comprise security gateway 1432, data center 1434, cloud controller 1436, data storage 1438 and provisioning tool 1440.

The above-described hardware description is a non-limiting example of corresponding structure for performing the functionality described herein.

Obviously, numerous modifications and variations of the present disclosure are possible in light of the above teachings. It is therefore to be understood that within the scope of the appended claims, the invention may be practiced otherwise than as specifically described herein.

1. An apparatus having a circuitry for transferring electrical current, the circuitry comprising:
a voltage-controlled current source (VCCS) component 102 having a pair of input terminals with an input voltage signal being applied at a first input terminal of the pair of input terminals;
a feedback network 104 connected to an output of the VCCS component and the first input terminal; and
a feedforward network 106 connected to the output of the VCCS component and configured to produce an output current signal at an output terminal of the apparatus,
wherein the feedback network 104 performs a phase-shifting operation on a voltage signal at an output of the VCCS component and feeds back a first phase-shifted voltage signal to the first input terminal,
wherein feedforward network 106 performs a phase-shifting operation on the voltage signal to generate a second phase-shifted voltage signal at the output terminal, the second phase-shifted voltage signal causing the output current signal to flow through the feedforward network 106, wherein the feedforward network 106 controls a specified gain of the output current signal over an input current signal at the first input terminal based on an impedance of the feedforward network 106.

2. The apparatus of claim 1, wherein the feedback network 104 includes “N” number of inverter components connected in parallel, and the feedforward network 106 includes “M” number of inverter components connected in parallel.

3. The apparatus of claim 2, wherein the specified gain of the output current signal is determined based on a ratio of M:N.

4. The apparatus of claim 3, wherein the specified gain of the output current signal is dependent on the ratio of M:N when electrical characteristics of inverters in the feedback network and the feedforward network match.

5. The apparatus of claim 1, wherein the first input terminal has a lower impedance compared to impedance at the output terminal.

6. The apparatus of claim 1, wherein the specified gain is configured to be unity by adjusting impedances of the feedback network and the feedforward network.

7. The apparatus of claim 6, wherein the specified gain is configured to be unity based on:
a first resistance value of the feedback network and an open loop gain of the VCCS component being increased to cause an impedance of the first terminal to be lesser than a first specified threshold, wherein the open loop gain of the VCCS component is determined based on an output resistance value of the VCCS component and a total output impedance of the VCCS component; and
a second resistance value of the feedforward network being increased to cause an impedance of the output terminal to be greater than a second specified threshold.

8. The apparatus of claim 7, wherein the total output impedance of the VCCS component is determined based on input impedances of the feedback network and the feedforward network.

9. The apparatus of claim 7, wherein the first resistance value of the feedback network is configured to be greater than a specified threshold resistance for a voltage gain of the apparatus to be unity or less than a third specified threshold, wherein the voltage gain is determined based on an output voltage signal at the output terminal and the input voltage signal at the first input terminal.

10. The apparatus of claim 1, wherein the output current signal is determined based on the voltage signal at the output of the VCCS component and a combined impedance of the feedback network and the feedforward network.

11. The apparatus of claim 1, wherein the feedback network is configured to restrict a specified voltage gain of an output voltage signal over the input voltage signal to be unity by providing a negative feedback to the first input terminal.

12. The apparatus of claim 1, wherein the circuitry is integrated in a biomedical device.

13. A current conveyor apparatus for transferring electrical current, the apparatus comprising:
a voltage-controlled current source (VCCS) component having a pair of input terminals with an input voltage signal being applied at a first input terminal of the pair of input terminals;
a feedback network including “N” number of inverter components connected in parallel, wherein the feedback network is connected to an output of the VCCS component and the first input terminal; and
a feedforward network including “M” number of inverter components connected in parallel, wherein the feedforward network is connected to the output of the VCCS component and configured to produce an output current signal at an output terminal of the apparatus, wherein the output current signal has a specified gain that is determined based on a ratio of M:N.

14. The apparatus of claim 13, wherein the feedback network performs a phase-shifting operation on a voltage signal at an output of the VCCS component and feeds back a first phase-shifted voltage signal to the first input terminal.

15. The apparatus of claim 14, wherein the feedforward network performs a phase-shifting operation on the voltage signal to generate a second phase-shifted voltage signal at the output terminal, the second phase-shifted voltage signal causing the output current signal to flow through the feedforward network.

16. The apparatus of claim 13, wherein the feedforward network controls the specified gain of the output current signal based on an impedance of the feedforward network.

17. The apparatus of claim 13, wherein the specified gain of the output current signal is dependent on the ratio of M:N when electrical characteristics of the inverters in the feedback network and the feedforward network match.

18. The apparatus of claim 13, wherein the specified gain is be configured to be unity by adjusting impedances of the feedback network and the feedforward network, wherein the adjusting includes:
increasing a first resistance value of the feedback network and an open loop gain of the VCCS component to cause an impedance of the first terminal to be lesser than a first specified threshold, wherein the open loop gain of the VCCS component is determined based on an output resistance value of the VCCS component and a total output impedance of the VCCS component, and
increasing a second resistance value of the feedforward network to cause an impedance of the output terminal to be greater than a second specified threshold.

19. The apparatus of claim 18, wherein the first resistance value of the feedback network is configured to be greater than a specified threshold resistance for a voltage gain of the apparatus to be unity or less than a third specified threshold, wherein the voltage gain is determined based on an output voltage signal at the output terminal and the input voltage signal at the first input terminal.

20. The apparatus of claim 13, wherein the feedback network is configured to restrict a specified voltage gain of an output voltage signal over the input voltage signal to be unity by providing a negative feedback to the first input terminal.
